(19) United States
(12) Patent Application Publication
(10) Pub. No.: US 2026/0090136 A1
(43) Pub. Date: Mar. 26, 2026

(54) PHOTODETECTION ELEMENT, INFORMATION TERMINAL DEVICE, COMMUNICATION SYSTEM, AND METHOD FOR MANUFACTURING A PHOTODETECTION ELEMENT

(71) Applicant: TDK Corporation, Tokyo (JP)

(72) Inventors: Takekazu YAMANE, Tokyo (JP); Tomohito Mizuno, Tokyo (JP); Tetsuya Shibata, Tokyo (JP)

(73) Assignee: TDK Corporation, Tokyo (JP)

(21) Appl. No.: 19/325,133

(22) Filed: Sep. 10, 2025

(30) Foreign Application Priority Data
Sep. 20, 2024 (JP) 2024-163869

(51) Int. Cl. H10F 77/40; H10F 71/00; H10F 77/60

(52) U.S. Cl. CPC H10F 77/407; H10F 71/134; H10F 77/60

(57) ABSTRACT

A photodetection element that concentrates irradiated light into a narrow area to suppress loss of light energy and perform efficient photodetection. The photodetection element includes a lens, a magnetic element including a first ferromagnetic layer, a second ferromagnetic layer, and a spacer layer sandwiched between the first ferromagnetic layer and the second ferromagnetic layer, and a high refractive index layer disposed between the lens and the magnetic element and having a refractive index larger than that of the lens, wherein light that passes through the lens and the high refractive index layer is irradiated onto the magnetic element.

### TECHNICAL FIELD

The present invention relates to a photodetection element, information terminal device, communication system, and method for manufacturing a photodetection element.

### BACKGROUND ART

Photoelectric conversion elements such as photodetection elements are used in various applications. For example, Patent Document 1 describes a receiving device that receives an optical signal using a photodiode. The photodiode is, for example, a pn junction diode and the like using a semiconductor pn junction and converts light into an electrical signal. For example, Patent Document 2 describes an optical sensor using a semiconductor pn junction and an image sensor using this optical sensor.

Furthermore, for example, Patent Document 3 discloses an optical sensor using a magnetic element and a receiving device using this optical sensor, and Patent Document 4 discloses a technology that combines an optical sensor using a magnetic element with a metalens.

### CITATION LIST

### Patent Document

[Patent document 1] Japanese Patent Application Publication No. 2001-292107
[Patent document 2] U.S. Pat. No. 9,842,874
[Patent document 3] Japanese Patent Application Publication No. 2022-69387
[Patent document 4] Japanese Patent Application Publication No. 2023-110453

### SUMMARY OF THE INVENTION

### Problems to be Solved by the Invention

Photodetection elements using semiconductor pn junctions are widely used, but new photodetection elements are needed for further development. In addition, when the photodetection element is very small, it is necessary to concentrate the light in a small area to reduce the spot of the irradiated light to increase the energy efficiency of the light irradiated to the photodetection element.

The present invention has been made in consideration of the above problems and has an object to provide a photodetection element that concentrates the irradiated light in a small area to suppress the loss of light energy, thereby performing efficient photodetection.

### Means for Solving the Problem

To achieve the above object, the photodetection element according to the present invention comprises a lens; a magnetic element including a first ferromagnetic layer, a second ferromagnetic layer, and a spacer layer sandwiched between the first ferromagnetic layer and the second ferromagnetic layer; and a high refractive index layer disposed between the lens and the magnetic element and having a refractive index larger than that of the lens, wherein light that passes through the lens and the high refractive index layer is irradiated onto the magnetic element.

By this configuration, the photodetection element according to the present invention can reduce the spot of light irradiated on the magnetic element by passing the light through the high refractive index layer having a refractive index larger than that of the lens. By reducing the spot of light, the thermal energy generated by the light can be efficiently absorbed by the magnetic element, thereby improving the sensitivity of the photodetection element.

In the photodetection element according to the present invention, the lens may be a metalens which comprises a plurality of nanostructures arranged two dimensionally.

By this configuration, the photodetection element of the present invention can be produced in a consistent production process from the magnetic element to the metalens by using a metalens having a plurality of nanostructures arranged two dimensionally as the lens, which makes the production process easier, thereby making it possible to produce a microlens suitable for a micromagnetic element.

The photodetection element of the present invention may comprise a high thermal conductivity layer provided between the lens and the magnetic element and having a thermal conductivity higher than that of the high refractive index layer.

By this configuration, the photodetection element of the present invention provided with the high thermal conductivity layer can improve the heat dissipation performance of heat generated in the photodetection element.

In the photodetection element of the present invention, the high refractive index layer may have a structure which has an area of a cross-section perpendicular to the optical axis of the lens gradually decreasing from the lens toward the magnetic element.

By this configuration, the photodetection element of the present invention can efficiently arrange a high refractive index layer in the optical path on which the light incident on the metalens travels to the magnetic element.

In the photodetection element of the present invention, the high refractive index layer may have a structure which has an area of a cross-section perpendicular to the optical axis of the lens decreasing stepwise from the lens toward the magnetic element.

By this configuration, the photodetection element of the present invention can efficiently arrange the high refractive index layer using a simple production process along the optical path of the light incident on the metalens until the light reaches the magnetic element.

In the photodetection element of the present invention, the high refractive index layer may further be configured in such manner that the periphery of the part where the area of the cross-section perpendicular to the optical axis of the lens gradually decreases or stepwise is surrounded by the high thermal conductivity layer.

By this configuration, the photodetection element of the present invention can enhance the heat dissipation properties of heat generated by the magnetic element by surrounding the periphery of the high refractive index layer with the high thermal conductivity layer.

In the photodetection element according to the present invention, the high refractive index layer may be made of at least one material selected from the group consisting of germanium, silicon, tantalum oxide, silicon nitride, titanium oxide, gallium oxide, hafnium oxide, niobium oxide, zinc sulfide, zirconium oxide, and cerium oxide.

The above material has a high refractive index and can ensure necessary light transmission, so that the material is suitable for the high refractive index layer of the photodetection element according to the present invention.

In order to achieve the above object, the photodetection element according to the present invention comprises a lens; a magnetic element including a first ferromagnetic layer, a second ferromagnetic layer, and a spacer layer sandwiched between the first ferromagnetic layer and the second ferromagnetic layer; an insulating layer provided to cover the periphery of the magnetic element; and a high refractive index layer having a refractive index larger than that of the insulating layer, wherein light that passes through the lens and the high refractive index layer is irradiated onto the magnetic element.

By this configuration, the photodetection element of the present invention can reduce the spot of light irradiated on the magnetic element by passing the light through the high refractive index layer which has a refractive index larger than that of the insulating layer. By reducing the spot of light, the thermal energy generated by the light can be efficiently absorbed by the magnetic element, thereby improving the sensitivity of the photodetection element.

### Effects of the Invention

According to the present invention, a photodetection element can be provided to concentrate the irradiated light in a narrow area to suppress the loss of light energy, thereby making it possible to efficiently detect light.

### BRIEF DESCRIPTION OF DRAWINGS

FIG. 1 is a cross-sectional view showing the configuration of a photodetection element according to a first embodiment of the present invention.

FIG. 2 is a partially enlarged cross-sectional view showing the configuration of the magnetic element shown in FIG. 1.

FIG. 3A is a figure showing how light is focused by the lens shown in FIG. 1, and FIG. 3B is a figure showing how light is focused by the lens in a conventional photodetection element.

FIG. 4 is a cross-sectional view showing the configuration of a photodetection element according to a second embodiment of the present invention.

FIG. 5 is a plan view showing the configuration of a metalens in FIG. 4.

FIG. 6 is a figure showing how light is focused by the metalens shown in FIG. 4.

FIG. 7 is a cross-sectional view showing the configuration of a photodetection element according to a third embodiment of the present invention.

FIG. 8 is a cross-sectional view showing the configuration of a photodetection element according to a fourth embodiment of the present invention.

FIG. 9 is a cross-sectional view showing the configuration of a photodetection element according to a fifth embodiment of the present invention.

FIG. 10A is a plan view of FIG. 9, and FIG. 10B is a cross-sectional view taken along line A-A in FIG. 9.

FIG. 11 is a cross-sectional view showing the configuration of a photodetection element according to a sixth embodiment of the present invention.

FIG. 12A is a plan view of FIG. 11, and FIG. 12B is a cross-sectional view taken along line B-B in FIG. 11.

FIG. 13 is a cross-sectional view showing the configuration of a photodetection element according to a seventh embodiment of the present invention.

FIG. 14A is a plan view of FIG. 13, and FIG. 14B is a cross-sectional view taken along line C-C in FIG. 13.

FIG. 15 is a cross-sectional view showing the configuration of a photodetection element according to an eighth embodiment of the present invention.

FIG. 16A is a plan view of FIG. 15, and FIG. 16B is a cross-sectional view taken along line D-D of FIG. 15.

### DETAILED DESCRIPTION OF EMBODIMENTS

Hereinafter, the embodiments of the present invention will be described in detail with reference to the drawings. For ease of understanding, the scale of each part in the drawings may differ from the actual scale. In the xyz Cartesian coordinate system set in the drawings, the x-axis direction and the y-axis direction are horizontal, and the z-axis direction is vertical. The positive direction of the z-axis is also called the upward direction, while the negative direction of the z-axis is also called the downward direction, but this has nothing to do with the direction of gravity. In directions such as parallel, right angle, orthogonal, horizontal, vertical, up and down, left and right, deviations are allowed to the extent that do not impair the effect of the embodiment. In addition, a symbol “˜” indicating a numerical range means that the numerical values written before and after the numerical range are included as the lower and upper limits.

### First Embodiment

First, the first embodiment of the present invention will be described.

### (Configuration)

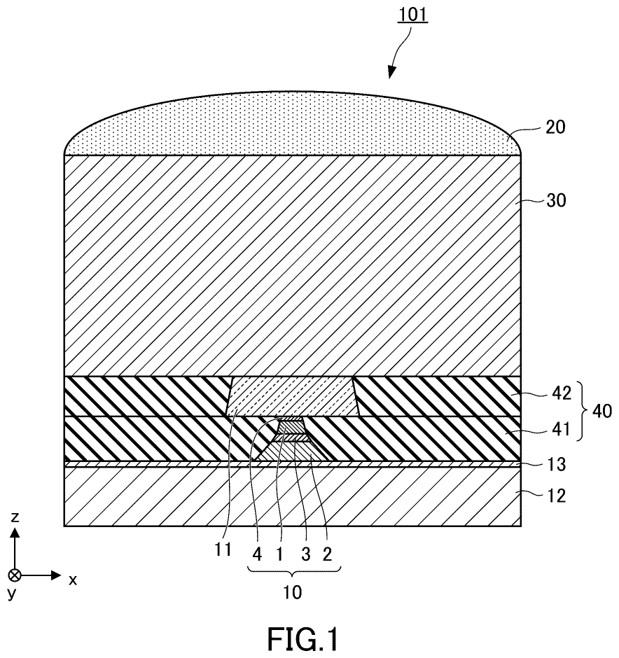

FIG. 1 is a cross-sectional view showing the configuration of a photodetection element 101 according to a first embodiment of the present invention. As shown in FIG. 1, the photodetection element 101 has a lens 20 and a magnetic element 10, and is provided with a high refractive index layer 30 between the lens 20 and the magnetic element 10. The high refractive index layer 30 has a refractive index larger than that of the lens 20. The magnetic element 10 is irradiated with light that passes through the lens 20 and the high refractive index layer 30. The magnetic element 10 detects the light irradiated to the magnetic element 10. The magnetic element 10 converts the light irradiated to the magnetic element 10 into an electrical signal. This electrical signal is extracted using a first electrode 11 and a second electrode 12 provided above and below the magnetic element 10. The lens 20 focuses the light toward the magnetic element 10. The magnetic element 10 is disposed, for example, at the focal position of the light focused by the lens 20. The photodetection element 101 may be columnar, for example, prismatic, cylindrical, and the like.

The “light” described in this specification is not limited to visible light but may be infrared light which has a wavelength longer than that of the visible light or ultraviolet light which has a wavelength shorter than that of the visible light. The wavelength of the visible light is, for example, 380 nm or more and less than 800 nm. The wavelength of the infrared light is, for example, 800 nm or more and 1 mm or less. The wavelength of the ultraviolet light is, for example, 200 nm or more and less than 380 nm.

Each component will be described hereinafter.

### (Magnetic Element)

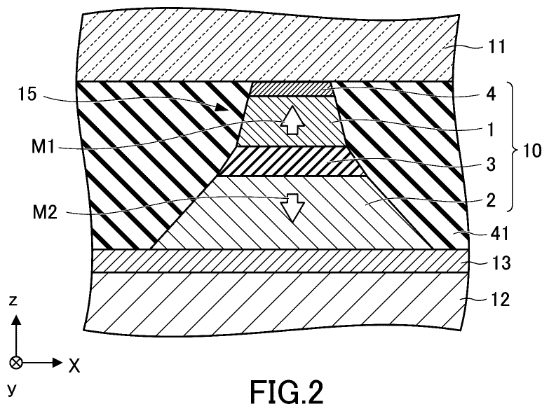

FIG. 2 is a partially enlarged cross-sectional view showing the configuration of the magnetic element 10 of FIG. 1. As shown in FIG. 2, the magnetic element 10 includes at least a first ferromagnetic layer 1, a second ferromagnetic layer 2, and a spacer layer 3 sandwiched between the first ferromagnetic layer 1 and the second ferromagnetic layer 2. In FIG. 2, the second ferromagnetic layer 2, the spacer layer 3, the first ferromagnetic layer 1, and a cap layer 4 are laminated in this order in the positive direction of the z-axis to form a laminate 15. The laminate 15 constituting the magnetic element 10 may further include other layers such as a third ferromagnetic layer, a buffer layer, a seed layer, a magnetic coupling layer, and a perpendicular magnetization induction layer if necessary.

As shown in FIGS. 1 and 2, a first electrode 11 is formed on the lens 20 side of the laminate 15, and a second electrode 12 is formed on the lens 20 opposite side of the laminate 15 through a cap layer 13. The magnetic element 10, when called as such may include the first electrode 11, the second electrode 12, the cap layer 13, the insulating layer 40 other than the laminate 15. The cap layer 4 is located between the first ferromagnetic layer 1 and the first electrode 11, while the cap layer 13 is located between the second ferromagnetic layer 2 and the second electrode 12. The insulating layer 40 is located between the high refractive index layer 30 and the cap layer 13 or the second electrode 12 and is provided to cover the periphery of the laminate 15 and the first electrode 11.

The magnetic element 10 is, for example, a magnetic tunnel junction (MTJ) element in which the spacer layer 3 is made of an insulating material. In this case, the magnetic element 10 can exhibit a tunnel magnetoresistance (TMR: Tunnel Magneto Resistance) effect. The resistance value of the magnetic element 10 changes when the magnetic element 10 is irradiated with light from the outside. The resistance value of the magnetic element 10 in the z-axis direction (resistance value when a current is passed in the z-axis direction) changes in response to the relative change between the state of magnetization M1 of the first ferromagnetic layer 1 and the state of magnetization M2 of the second ferromagnetic layer 2. For example, the resistance value of the magnetic element 10 in the z-axis direction changes in response to the change in the relative angle between the direction of magnetization M1 of the first ferromagnetic layer 1 and the direction of magnetization M2 of the second ferromagnetic layer 2. Also, for example, the resistance value of the magnetic element 10 in the z-axis direction changes in response to the change in the magnitude of magnetization M1 of the first ferromagnetic layer 1.

Furthermore, for example, when the spacer layer 3 is made of metal, the magnetic element 10 can exhibit a giant magnetoresistance (GMR) effect. Such an element is called a GMR element. When the magnetic element 10 is a GMR element, the resistance value in the z-axis direction (resistance value when a current is passed in the z-axis direction) changes in response to the relative change between the state of magnetization M1 of the first ferromagnetic layer 1 and the state of magnetization M2 of the second ferromagnetic layer 2. The magnetic element 10 may be called an MTJ element, a GMR element, or the like, depending on the material of the spacer layer 3, but is also collectively called a magnetoresistance effect element. The total thickness of the magnetic element 10 is, for example, 15 nm˜40 nm.

The magnetic element 10 may have a ferromagnetic material whose magnetization state changes in response to the irradiation of light and may be made of any material in which the resistance value changes in response to the change in the magnetization state. The magnetic element 10 may be, for example, able to use an anisotropic magnetoresistance (AMR) effect element, a colossal magnetoresistance (CMR) effect element, or the like, in addition to the above-mentioned MTJ element and GMR element.

The magnetic element 10 is disposed at the focal position of the light in the band range of use focused by the lens 20. The focal position of the light in the band range of use preferably overlaps, for example, with the first ferromagnetic layer 1. For example, when the visible light is used, the magnetic element 10 is disposed at the focal position of the light in a specific wavelength range within the wavelength range of 380 nm or more and less than 800 nm. For example, when infrared light is used, the magnetic element 10 is disposed at the focal position of the light in a specific wavelength range within the wavelength range of 800 nm or more and less than 1 mm. For example, when ultraviolet light is used, the magnetic element 10 is disposed at the focal position of the light in a specific wavelength range within the wavelength range of 200 nm or more and less than 380 nm.

### <First Ferromagnetic Layer>

The first ferromagnetic layer 1 is a photodetection layer whose magnetization state changes when light is irradiated from the outside. The first ferromagnetic layer 1 is also called a magnetization free layer. The magnetization free layer is a layer including a magnetic material whose magnetization state changes when a specific external energy is applied thereto. The specific external energy is, for example, light irradiated from the outside, a current flowing in the z-axis direction of the magnetic element 10, an external magnetic field, and the like. The magnetization M1 of the first ferromagnetic layer 1 has a state changed in response to the intensity of the irradiated light.

The first ferromagnetic layer 1 includes a ferromagnetic material. The first ferromagnetic layer 1 includes at least one of magnetic elements such as Co, Fe, or Ni. The first ferromagnetic layer 1 may include elements such as B, Mg, Hf, Gd, and the like, in addition to the magnetic elements as described above. The first ferromagnetic layer 1 may be, for example, an alloy including a magnetic element and a nonmagnetic element. The first ferromagnetic layer 1 may be composed of multiple layers. The first ferromagnetic layer 1 may be, for example, a CoFeB alloy, a laminate in which a CoFeB alloy layer is sandwiched between Fe layers, or a laminate in which a CoFeB alloy layer is sandwiched between CoFe layers. In general, “ferromagnetic property” includes “ferrimagnetic property”. The first ferromagnetic layer 1 may exhibit ferrimagnetic property. Alternatively, the first ferromagnetic layer 1 may exhibit ferromagnetic property that is not ferrimagnetic. For example, a CoFeB alloy exhibits ferromagnetic property that is not ferrimagnetic.

The first ferromagnetic layer 1 may be an in-plane magnetized film having an easy axis of magnetization in the in-plane direction (any direction in the xy plane) or a perpendicular magnetized film having an easy axis of magnetization in the direction perpendicular to the film plane (z-axis direction).

The film thickness of the first ferromagnetic layer 1 is, for example, 1 nm˜5 nm. The film thickness of the first ferromagnetic layer 1 is preferably, for example, 1 nm˜2 nm. When the first ferromagnetic layer 1 is a perpendicular magnetic film, if the film thickness of the first ferromagnetic layer 1 is thin, the perpendicular magnetic anisotropy applied effect from the layers above and below the first ferromagnetic layer 1 is strengthened, and the perpendicular magnetic anisotropy of the first ferromagnetic layer 1 is enhanced. In other words, if the perpendicular magnetic anisotropy of the first ferromagnetic layer 1 is high, the force that causes the magnetization M1 to return to the z-axis direction is strengthened. On the other hand, if the film thickness of the first ferromagnetic layer 1 is thick, the perpendicular magnetic anisotropy applied effect from the layers above and below the first ferromagnetic layer 1 is relatively weakened, and the perpendicular magnetic anisotropy of the first ferromagnetic layer 1 is weakened.

If the film thickness of the first ferromagnetic layer 1 is thin, the volume of the ferromagnetic body becomes small, and if it is thick, the volume of the ferromagnetic body becomes large. The sensitivity of the magnetization of the first ferromagnetic layer 1 to the application of external energy is inversely proportional to the product (KuV) of the magnetic anisotropy (Ku) and volume (V) of the first ferromagnetic layer 1. In other words, the smaller the product of the magnetic anisotropy and the volume of the first ferromagnetic layer 1, the higher the light reactivity. From this viewpoint, to increase the light reactivity, it is preferable to appropriately design the magnetic anisotropy of the first ferromagnetic layer 1, thereby reducing the volume of the first ferromagnetic layer 1.

If the film thickness of the first ferromagnetic layer 1 is thicker than 2 nm, an insertion layer made of, for example, Mo or W may be provided in the first ferromagnetic layer 1. That is, the first ferromagnetic layer 1 may be a laminate in which a ferromagnetic layer, an insertion layer, and a ferromagnetic layer are laminated in this order in the z-axis direction. The interface magnetic anisotropy at the interface between the insertion layer and the ferromagnetic layer increases the perpendicular magnetic anisotropy of the entire first ferromagnetic layer 1. The film thickness of the insertion layer is, for example, 0.1 nm˜1.0 nm.

### <Second Ferromagnetic Layer>

The second ferromagnetic layer 2 is a magnetization fixed layer. The magnetization fixed layer is a layer made of a magnetic material in which the state of magnetization is more difficult to change than that of the magnetization free layer when a predetermined external energy is applied thereto. For example, the magnetization direction of the magnetization fixed layer is more difficult to change than that of magnetization free layer when a predetermined external energy is applied thereto. Also, for example, the magnitude of magnetization of the magnetization fixed layer is more difficult to change than that of the magnetization free layer when a predetermined external energy is applied thereto. The coercive force of the second ferromagnetic layer 2 is, for example, larger than the coercive force of the first ferromagnetic layer 1. The second ferromagnetic layer 2 has an easy magnetization axis in the same direction as that of the first ferromagnetic layer 1. The second ferromagnetic layer 2 may be an in-plane magnetized film or a perpendicular magnetized film.

The material constituting the second ferromagnetic layer 2 is, for example, the same as that of the first ferromagnetic layer 1. The second ferromagnetic layer 2 may be, for example, a multilayer film in which Co having a thickness of 0.4 nm˜1.0 nm and Pt having a thickness of 0.4 nm˜1.0 nm are alternately laminated several times. The second ferromagnetic layer 2 may be, for example, a laminate in which Co having a thickness of 0.4 nm˜1.0 nm, Mo having a thickness of 0.1 nm˜0.5 nm, CoFeB alloy having a thickness of 0.3 nm˜1.0 nm, and Fe having a thickness of 0.3 nm˜1.0 nm are laminated in this order.

### <Spacer Layer>

The spacer layer 3 is a layer disposed between the first ferromagnetic layer 1 and the second ferromagnetic layer 2. The spacer layer 3 is a layer made of a conductor, an insulator, or a semiconductor, or a layer including a current-passing point made of a conductor in an insulator. The spacer layer 3 is, for example, a nonmagnetic layer. The film thickness of the spacer layer 3 can be adjusted in response to the orientation direction of the magnetization of the first ferromagnetic layer 1 and the magnetization of the second ferromagnetic layer 2 in the initial state which is described hereinafter.

When the spacer layer 3 is made of an insulating material, the material which contains aluminum oxide, magnesium oxide, titanium oxide, silicon oxide, and the like can be used as the material of the spacer layer 3. These insulating materials may also contain elements such as Al, B, Si, Mg, and magnetic elements such as Co, Fe, Ni. A high magnetoresistance change rate can be obtained by adjusting the film thickness of the spacer layer 3 so that a high TMR effect is generated between the first ferromagnetic layer 1 and the second ferromagnetic layer 2. To efficiently utilize the TMR effect, the film thickness of the spacer layer 3 may be about 0.5 nm˜5.0 nm, or about 1.0 nm˜2.5 nm.

When the spacer layer 3 is made of a nonmagnetic conductive material, the conductive materials such as Cu, Ag, Au, or Ru can be used. To efficiently utilize the GMR effect, the film thickness of the spacer layer 3 may be about 0.5 nm˜5.0 nm, or about 2.0 nm˜3.0 nm.

When the spacer layer 3 is made of a nonmagnetic semiconductor material, the materials such as zinc oxide, indium oxide, tin oxide, germanium oxide, gallium oxide, or indium tin oxide (ITO) can be used. In this case, the film thickness of the spacer layer 3 may be about 1.0 nm˜4.0 nm.

When a layer including a current-passing point formed by a conductor in a nonmagnetic insulator is used as the spacer layer 3, a structure including a current-passing point formed by a nonmagnetic conductor such as Cu, Au, or Al in a nonmagnetic insulator made of aluminum oxide or magnesium oxide may be used. The conductor may also be made of magnetic elements such as Co, Fe, or Ni. In this case, the film thickness of the spacer layer 3 may be about 1.0 nm˜2.5 nm. The current-passing point is, for example, a columnar body with a diameter of 1 nm˜5 nm when viewed from a direction perpendicular to the film surface.

### <Cap Layer>

The cap layer 4 is provided between the first ferromagnetic layer 1 and the first electrode 11. The cap layer 4 may include a perpendicular magnetization induction layer (not shown) that is laminated on the first ferromagnetic layer 1 and in contact with the first ferromagnetic layer 1. The cap layer 4 prevents damage to the lower layers during the production process and enhances the crystallinity of the lower layer during annealing. The film thickness of the cap layer 4 is, for example, 10 nm or less to have the first ferromagnetic layer 1 irradiated with sufficient light.

### <Insulating Layer>

The insulating layer 40 includes an insulating layer 41 that fills the periphery of the laminate 15 and an insulating layer 42 that fills the periphery of the first electrode 11. The insulating layer 41 and the insulating layer 42 are made of the same material but may be made of different materials. The insulating layer 40 (insulating layer 41 and/or insulating layer 42) is, for example, oxide, nitride, or oxynitride of Si, Al, or Mg. The insulating layer 40 (insulating layer 41 and/or insulating layer 42) is, for example, silicon oxide (SiOx), silicon nitride (SiNx), silicon carbide (SiC), chromium nitride, silicon carbonitride (SiCN), silicon oxynitride (SiON), aluminum oxide (Al₂O₃), zirconium oxide (ZrOx), and the like.

### <First Electrode>

The first electrode 11 is, for example, disposed on the lens 20 side of the magnetic element 10. Incident light is irradiated from the first electrode 11 side to the magnetic element 10 and is irradiated to at least the first ferromagnetic layer 1. The first electrode 11 is made of a material having electrical conductivity. The first electrode 11 is, for example, a transparent electrode that is transparent to light in the wavelength range used. It is preferable that the first electrode 11 pass, for example, 80% or more of the light in the wavelength range used. The first electrode 11 is, for example, an oxide such as indium tin oxide (ITO), indium zinc oxide (IZO), zinc oxide (ZnO), or indium gallium zinc oxide (IGZO). The first electrode 11 may have a structure in which a plurality of metal columns are included in a transparent electrode material of such oxide.

It is not essential to use such a transparent electrode material as the first electrode 11, but a metal material such as Au, Cu, or Al may be used in a thin film thickness to allow the irradiated light to reach the first ferromagnetic layer 1. When a metal is used as the material of the first electrode 11, the film thickness of the first electrode 11 is, for example, 3 nm˜10 nm. The first electrode 11 may also have an anti-reflection film on the irradiation surface to which light is irradiated.

### <Second Electrode>

The second electrode 12 is made of a material that has electrical conductivity. The second electrode 12 is made of, for example, a metal such as Cu, Al, or Au. Ta or Ti may be laminated above and below these metals. Also, a laminated film of Cu and Ta, a laminated film of Ta, Cu and Ti, or a laminated film of Ta, Cu and TaN may be used. Also, TiN or TaN may be used as the second electrode 12. The film thickness of the second electrode 12 is, for example, 200 nm˜800 nm.

The second electrode 12 may be transparent to the light irradiated to the magnetic element 10. Similarly to the first electrode 11, as the material of the second electrode 12, a transparent electrode material such as indium tin oxide (ITO), indium zinc oxide (IZO), zinc oxide (ZnO), indium gallium zinc oxide (IGZO), or other oxide may be used. Even when light is irradiated from the first electrode 11, the light may reach the second electrode 12 depending on the intensity of the light. In this case, the second electrode 12 is configured to include an oxide transparent electrode material, and thus the reflection of light at the interface between the second electrode 12 and the layer in contact therewith can be suppressed as compared to when the second electrode 12 is configured of a metal.

### (High Refractive Index Layer)

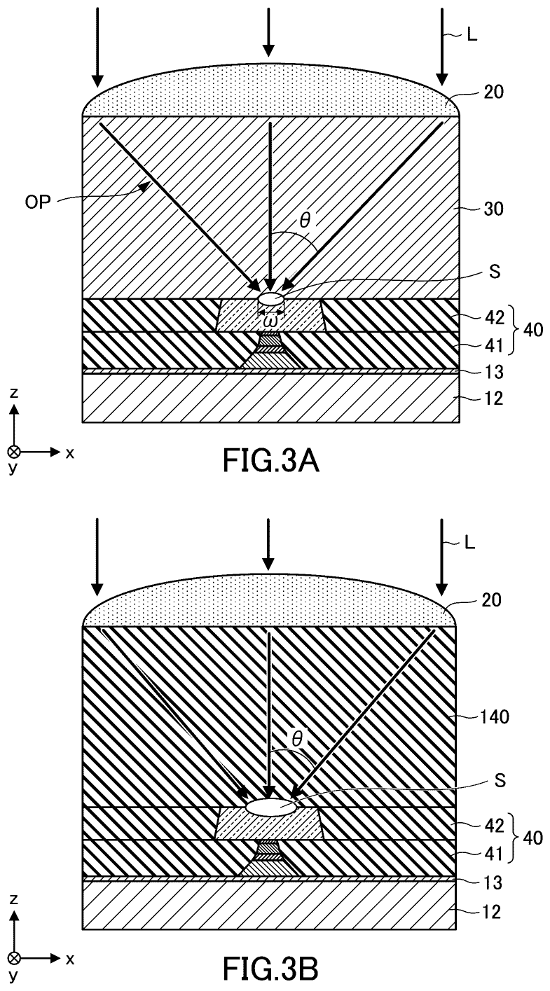

The high refractive index layer 30 may be configured of at least one material selected from the group consisting of, for example, germanium, silicon, tantalum oxide, silicon nitride, titanium oxide, gallium oxide, hafnium oxide, niobium oxide, zinc sulfide, zirconium oxide, and cerium oxide. The high refractive index layer 30 has, for example, a refractive index larger than that of the lens 20. The high refractive index layer 30 has, for example, a refractive index larger than that of the insulating layer 40. The high refractive index layer 30 has, for example, a refractive index larger than that of the insulating layer 140 provided between the lens and the magnetic element in a conventional photodetection element (see FIG. 3B). The high refractive index layer 30 is, for example, a transparent layer that is transparent to light in the wavelength range used. It is preferable that the high refractive index layer 30, for example, passes 80% or more of light in the wavelength range used. The film thickness of the high refractive index layer 30, i.e., the thickness in the z-axis direction, is, for example, 100 nm˜1 mm.

### (Lens)

The lens 20 is provided on the high refractive index layer 30 and is adapted to focus the light incident on the lens 20 and to irradiate the light on the magnetic element 10. The lens 20 is, for example, a microlens. The lens 20 may be formed during the wafer process in which the photodetection element 101 is formed.

The light incident on the lens 20 may be light that passes through a polarizing filter. The photodetection element 101 may have a polarizing filter (not shown) on the side of the lens 20 opposite to the magnetic element 10. If the light incident on the photodetection element 101 is polarized light such as laser light, the polarizing filter may not be required.

### Explanation of the Principle

FIG. 3A is a figure showing how light L is focused by the lens 20. Light L incident on the photodetection element 101 is focused by the lens 20 to form a light spot S through the focal length. In FIG. 3A, the light spot S is formed on the first electrode 11, but the position where the light spot S is formed is not limited to this and may be on the first ferromagnetic layer 1. If the focusing angle of the lens 20 is 0, and the refractive index of the high refractive index layer 30 is n, the aperture number NA is NA=n sin θ. If the wavelength of light is λ, the light spot diameter ω is ω=k λ/NA (k is a constant). Therefore, even with the same lens diameter and focal length, the focused light spot diameter ω can be reduced by increasing the refractive index n of the high refractive index layer 30.

On the other hand, FIG. 3B is a figure showing how light is focused by a lens in a conventional photodetection element. As shown in FIG. 3B, in the conventional photodetection element, an insulating layer 140 is formed between the lens 20 and the magnetic element. The insulating layer 140 has a refractive index smaller than that of the high refractive index layer 30 in FIG. 3A. Therefore, in the conventional photodetection element in FIG. 3B, when the lens diameter and focal length are the same as those in the first embodiment of the present invention, the spot diameter of the focused light becomes larger than that of the first embodiment shown in FIG. 3A.

### (Production Process)

The photodetection element 101 is obtained by sequentially fabricating the second electrode 12, the magnetic element 10, the first electrode 11, the high refractive index layer 30, and the lens 20.

The magnetic element 10 is fabricated by a lamination process for each layer, an annealing process, a processing process, and the like. First, the cap layer 13, the second ferromagnetic layer 2, the spacer layer 3, the first ferromagnetic layer 1, and the cap layer 4 are laminated on the second electrode 12 in this order. Each layer is formed by, for example, sputtering.

Then, the laminated film is annealed. The annealing temperature is, for example, 250° C.˜400° C. The laminated film is then processed into a columnar laminate 15 by photolithography and etching (ion milling, and the like.). The laminate 15 may be mesa-shaped, cylindrical, prismatic, truncated cone shaped, truncated pyramid shaped, or the like, either as a whole or for each layer. The shortest width of the laminate 15 as viewed from the z-axis direction is, for example, 10 nm˜1000 nm.

Then, an insulating layer 41 is formed to cover the side surface of the laminate 15. The insulating layer 41 may be laminated multiple times. Next, the upper surface of the cap layer 4 is exposed from the insulating layer 41 by chemical mechanical polishing, and a first electrode layer is formed on the cap layer 4 and the insulating layer 41 by sputtering. The first electrode layer is processed by photolithography and etching into a columnar or plate-shaped first electrode 11, for example, in a cylindrical shape, a prismatic shape, a truncated cone shape, a truncated pyramid shape, or the like. Next, an insulating layer 42 is embedded around the first electrode 11. Next, the upper surface of the first electrode 11 is exposed from the insulating layer 42, for example, by chemical mechanical polishing.

Next, a high refractive index layer 30 is formed on the first electrode 11 and the insulating layer 42. The high refractive index layer 30 may be laminated multiple times. Next, a lens 20 is provided on the high refractive index layer 30. The lens 20 is, for example, a microlens. Through the above process, the photodetection element 101 is obtained. In this way, in the production of the photodetection element 101, at least the components from the magnetic element 10 to the high refractive index layer 30 can be continuously formed by a vacuum film formation process.

### Explanation of Operation

Next, the operation of the photodetection element 101 according to the first embodiment will be described.

As shown in FIG. 3A, the light L incident on the photodetection element 101 is focused by the lens 20 to form a light spot S at the focus of the lens 20. The focus of the lens 20 is located on the magnetic element 10, preferably the first ferromagnetic layer 1, but may be located on the first electrode 11. That is, the light L passing through the lens 20 and the high refractive index layer 30 forms a light spot S and is irradiated to the magnetic element 10.

When the intensity of the light irradiated to the first ferromagnetic layer 1 changes, the state of the magnetization M1 of the first ferromagnetic layer 1 changes. The state of the magnetization M1 is, for example, the tilt angle of the magnetization M1 inclined with respect to the z-axis direction, the magnitude of the magnetization M1, and the like.

For example, when the intensity of the light irradiated to the first ferromagnetic layer 1 increases, the magnetization M1 of the first ferromagnetic layer 1 is inclined from its initial state due to the external energy caused by the light irradiation. The angle between the direction of the magnetization M1 of the first ferromagnetic layer 1 when the first ferromagnetic layer 1 is not irradiated with light and the direction of the magnetization M1 when the first ferromagnetic layer 1 is irradiated with light is, for example, larger than 0° and smaller than 90°. Alternatively, for example, when the intensity of the light irradiated to the first ferromagnetic layer 1 increases, the magnitude of the magnetization M1 decreases.

When the state of the magnetization M1 of the first ferromagnetic layer 1 changes, the resistance value of the magnetic element 10 in the z-axis direction changes due to the magnetoresistance effect. When a constant current (sense current) is passed in the positive or negative direction of the z-axis of the magnetic element 10 while using the first electrode 11 and the second electrode 12, an output voltage is obtained from the magnetic element 10. In other words, when the state of the magnetization M1 of the first ferromagnetic layer 1 changes, the output voltage from the magnetic element 10 also changes.

The intensity of the light irradiated to the first ferromagnetic layer 1 may take two values, for example, a first intensity and a second intensity. The first intensity may be the case where the intensity of the light irradiated to the first ferromagnetic layer 1 is zero. The intensity of the light irradiated to the first ferromagnetic layer 1 may be multi-valued or may change in an analog manner. When the intensity of the incident light is multi-valued, the output voltage of the magnetic element 10 may also be multi-valued, and when the intensity of the light changes in an analog manner, the output voltage of the magnetic element 10 may also change in an analog manner. The difference between these output voltages (resistance values) can be read from the photodetection element 101 as binary, multi-valued, or analog data.

In a state where the first ferromagnetic layer 1 is irradiated with light of the first intensity (referred to as the “initial state”), the magnetization M1 of the first ferromagnetic layer 1 and the magnetization M2 of the second ferromagnetic layer 2 may be parallel or anti-parallel, or the magnetization M1 and the magnetization M2 may be perpendicular to each other.

When magnetization M1 and magnetization M2 are parallel in the initial state, a sense current is passed from the first ferromagnetic layer 1 to the second ferromagnetic layer 2. By passing a sense current in this direction, a spin transfer torque in the same direction as the magnetization M2 of the second ferromagnetic layer 2 acts on the magnetization M1 of the first ferromagnetic layer 1, and the magnetization M1 and the magnetization M2 become parallel in the initial state. Also, by passing a sense current in this direction, it is possible to prevent the magnetization M1 of the first ferromagnetic layer 1 from reversing during operation.

When the magnetization M1 and the magnetization M2 are antiparallel in the initial state, it is preferable to pass a sense current from the second ferromagnetic layer 2 to the first ferromagnetic layer 1. By passing a sense current in this direction, a spin transfer torque acts on the magnetization M1 of the first ferromagnetic layer 1 in the opposite direction to the magnetization M2 of the second ferromagnetic layer 2, and in the initial state, the magnetizations M1 and M2 become antiparallel.

When the intensity of the light irradiated to the first ferromagnetic layer 1 returns to the first intensity, a spin transfer torque acts due to the sense current, or the state of the magnetization M1 of the first ferromagnetic layer 1 returns to its original state because of magnetic anisotropy, and the magnetic element 10 returns to its initial state.

In this way, the photodetection element 101 according to the first embodiment can focus the incident light L by the lens 20 and the high refractive index layer 30 to form a small diameter light spot and can irradiate the magnetic element 10, and thereby can convert a change in the intensity of the irradiated light into a change in the output voltage from the magnetic element 10. In other words, the photodetection element 101 can convert light into an electrical signal.

As described above, in the photodetection element 101 of the first embodiment, the light passes through the high refractive index layer 30, which has a refractive index larger than that of the lens 20, so that the spot of light irradiated on the magnetic element 10 can be made small. By making the light spot small, the thermal energy generated by the light can be efficiently absorbed by the magnetic element 10, and the sensitivity of the photodetection element 101 can be improved.

### Second Embodiment

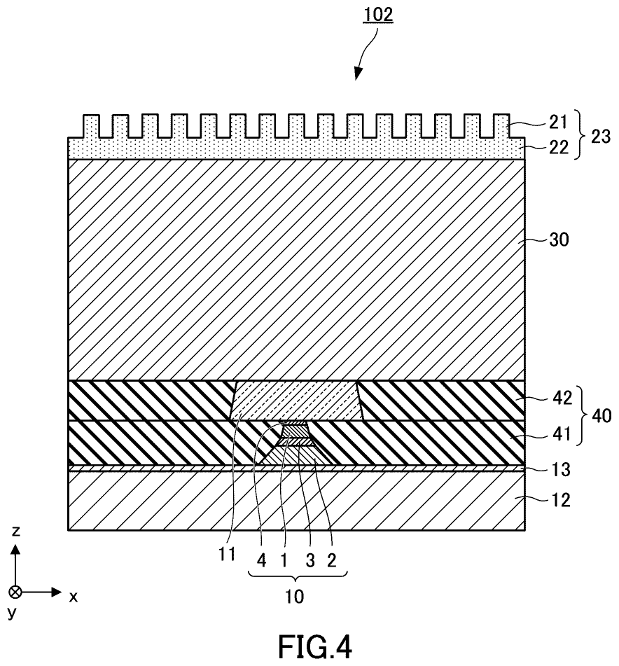

Next, a second embodiment of the present invention will be described. FIG. 4 is a cross-sectional view showing the configuration of a photodetection element 102 according to a second embodiment of the present invention. The second embodiment differs from the first embodiment in that the lens is a metalens 23. The other configurations are the same as those of the first embodiment, and the same components are denoted by the same reference numerals, so that the description of the same components will be omitted appropriately.

### (Metalens)

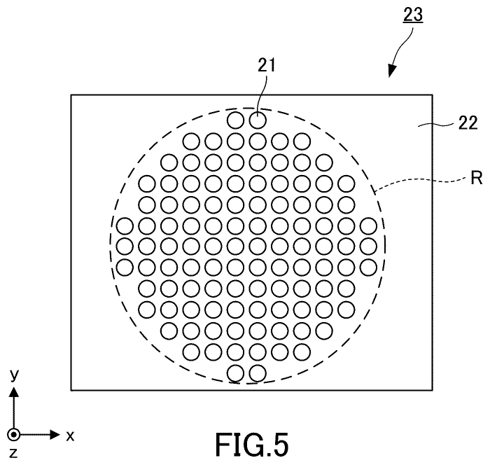

FIG. 5 is a plan view showing the configuration of the metalens 23 of FIG. 4. As shown in FIG. 5, the metalens 23 has a plurality of nanostructures 21 arranged two dimensionally on the xy plane. The nanostructures 21 may be arranged in a predetermined arrangement pattern, for example, in a circular region R on a base portion 22. The nanostructures 21 are, for example, cylindrical, but may also be prisms, rectangular parallelepipeds, and the like.

When the nanostructures 21 are cylindrical, the metalens 23 may include multiple types of nanostructures 21 with different diameters of the circular upper surface and different cylindrical heights. When the nanostructures 21 are rectangular parallelepipeds, the metalens 23 may change the arrangement angle of the nanostructures 21 in their position in the region R. The arrangement angle is an angle showing that the longitudinal direction of the rectangular upper surface of the nanostructure 21 is made with respect to a reference axis (for example, the x-axis direction). The distribution of the arrangement angle may have, for example, the regularity of the Pancharatnam Berry geometric phase. The size of the upper surface of the nanostructures 21 (the diameter of the circular upper surface in the case of a cylinder, the longitudinal length and the short directional width of the upper rectangular surface in the case of a rectangular parallelepiped) and the interval between adjacent nanostructures 21 are equal to or less than the wavelength of the light used.

The area of each of the nanostructures 21 contained in the circular region R in plan view seen from the z-axis direction may be changed in response to, for example, the distance from the center of the circular region R. The area of each of the nanostructures 21 contained in the circular region R in plan view seen from the z-axis direction may be made gradually smaller, for example, toward the outside from the center of the circular region R.

The metalens 23 is a lens that is applied with a metasurface. The metalens 23 functions as a lens by controlling the phase distribution of light. The metasurface exerts the function of a metamaterial by its planar structure. A metamaterial is a medium that has a negative refractive index, or a medium designed to have a refractive index (dielectric constant, magnetic permeability) that does not exist in nature. The metalens 23 can reduce the focal length, so the photodetection element 102 can be made smaller in size.

The metalens 23 includes, for example, a dielectric object in which surface plasmon excitation occurs. The metalens 23 also passes light in the band range of use. The metalens 23 may be made of at least one material selected from the group consisting of, for example, tantalum oxide, silicon nitride, titanium oxide, gallium oxide, silicon oxide, and aluminum oxide. The film thickness of the metalens 23, i.e., the thickness in the z-axis direction, is, for example, 100 nm˜10 μm.

The metalens 23 can control the phase distribution of light by adjusting the arrangement of the multiple nanostructures 21, the size of each nanostructure 21, and the arrangement period of the multiple nanostructures 21. In addition, by adjusting the size and arrangement period of the nanostructures 21, the focal lengths of the metalens 23 can be made the same even if the wavelengths of the incident light are different from each other.

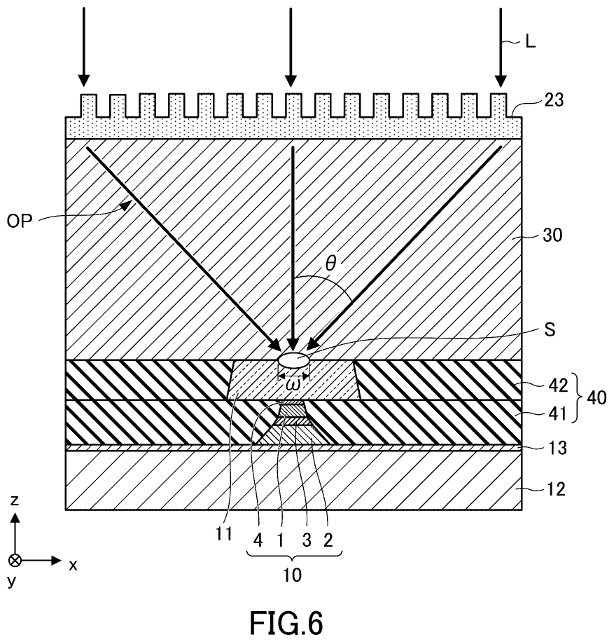

FIG. 6 is a figure showing how light is focused by the metalens 23 shown in FIG. 4 and FIG. 5. The light L incident on the photodetection element 102 is focused by the metalens 23 to form a light spot S at the focal length. In FIG. 6, the light spot S is formed at the position of the first electrode 11, but the position where the light spot S is formed is not limited to this, and it may be formed at the first ferromagnetic layer 1. As in FIG. 3A, if the light collection angle of the metalens 23 is 0 and the refractive index of the high refractive index layer 30 is n, the aperture number NA is NA=n·sin θ. If the wavelength of light is 2, the light spot diameter ω is ω=k·λ/NA (k is a constant). Therefore, even if the metalens has the same lens diameter and focal length, the focused light spot diameter ω can be reduced by increasing the refractive index n of the high refractive index layer 30 arranged between the metalens 23 and the magnetic element 10.

### (Production Process)

The production process of the second embodiment from the second electrode 12 to the high refractive index layer 30 is the same as that of the first embodiment. In the second embodiment, a base portion 22 is formed on the upper surface of the high refractive index layer 30, a resist having a predetermined pattern formed by photolithography is formed on the upper surface of the base portion 22, and dry etching is performed. A metalens 23 is formed by forming a plurality of nanostructures 21 of a predetermined pattern on the upper surface of the base portion 22 by dry etching. The above process makes it possible to obtain the photodetection element 102. In this way, in the production of the photodetection element 102, the components from the magnetic element 10 to the metalens 23 can be formed continuously by a vacuum film formation process.

As described above, in the photodetection element 102 of the second embodiment, the light passes, in the same manner as in the first embodiment, through the high refractive index layer 30 which has a refractive index larger than that of the metalens 23, so that the spot of light irradiated on the magnetic element 10 can be made smaller. This allows the thermal energy generated by the light to be efficiently absorbed by the magnetic element 10, thereby making it possible to improve the sensitivity of the photodetection element 102. In addition, the fact that the photodetection element 102 of the second embodiment uses a metalens 23 having a plurality of nanostructures 21 and arranged two dimensionally as a lens leads to the fact that the components from the magnetic element 10 to the metalens 23 can be produced in a consistent production process, thereby facilitating to make the production process and manufacturing a minute lens suitable for the minute magnetic element 10.

### Third Embodiment

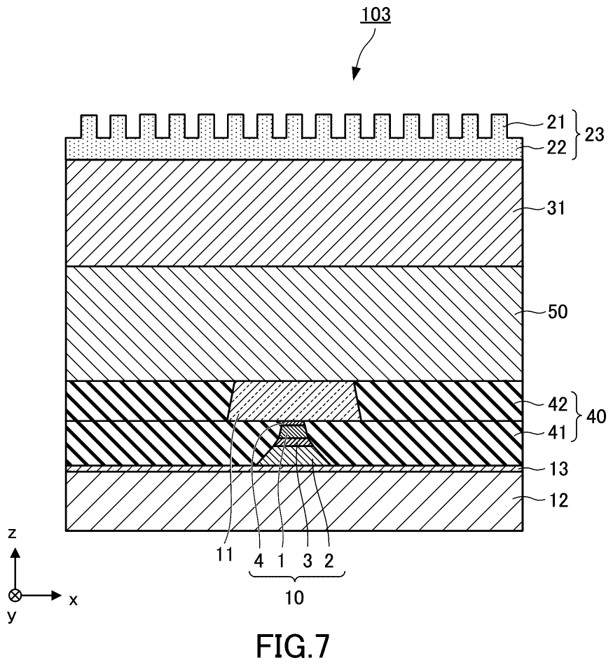

A third embodiment of the present invention will be described. FIG. 7 is a cross-sectional view showing the configuration of a photodetection element 103 according to the third embodiment of the present invention. The third embodiment differs from the second embodiment in that a high thermal conductivity layer 50 is provided between the metalens 23 and the magnetic element 10. The other configurations of the third embodiment are the same as those of the second embodiment, so that the same components are given the same reference numerals. Therefore, the description of the same components will be omitted appropriately.

### (High Thermal Conductivity Layer)

The high thermal conductivity layer 50 is provided with a predetermined thickness between the metalens 23 and the magnetic element 10, and between the high refractive index layer 31 and the magnetic element 10. Specifically, the high thermal conductivity layer 50 and the high refractive index layer 31 are laminated in this order on the first electrode 11 and the insulating layer 40, and the metalens 23 is provided on the high refractive index layer 31. The high thermal conductivity layer 50, for example, has a thermal conductivity higher than that of the high refractive index layer 31. The high thermal conductivity layer 50 may, for example, have a thermal conductivity higher than that of either or both the insulating layer 40 and the first electrode 11. The thermal conductivity of the high thermal conductivity layer 50 is, for example, larger than 40 W/m·K. A portion of the heat generated in the magnetic element 10 and the first electrode 11 is discharged through the high thermal conductivity layer 50.

The high thermal conductivity layer 50 is, for example, an insulator. The high thermal conductivity layer 50 may be, for example, composed of at least one material selected from the group consisting of silicon carbide, aluminum nitride, and boron nitride.

The high thermal conductivity layer 50 may be, for example, a metal. The high thermal conductivity layer 50 may be, for example, a nonmagnetic material. If the high thermal conductivity layer 50 is a nonmagnetic material, no leakage magnetic field is generated from the high thermal conductivity layer 50, thereby making it possible to suppress the magnetic properties of the magnetic element 10 from deteriorating. The high thermal conductivity layer 50 may contain, for example, copper, gold, or silver.

Even if the high thermal conductivity layer 50 is an insulator or a metal, the high thermal conductivity layer 50 can pass light in the band range of use therethrough. For example, the high thermal conductivity layer 50 preferably passes 80% or more of light in the used wavelength range therethrough.

As described above, the photodetection element 103 according to the third embodiment can convert light irradiated to the magnetic element 10 into an electrical signal by replacing the light irradiated to the magnetic element 10 with an output voltage from the magnetic element 10. In addition, the high thermal conductivity layer 50 with high thermal conductivity is placed on the outside of the magnetic element 10 that generates heat in response to irradiation with light, thereby making it possible to increase heat dissipation from the magnetic element 10 through the first electrode 11 or the insulating layer 40. That is, the magnetic element 10 is cooled quickly, and the magnetization M1 quickly returns to the initial state when the light irradiation to the first ferromagnetic layer 1 is stopped. If the magnetization M1 of the first ferromagnetic layer 1 quickly returns to the initial state, the light responsive characteristics of the photodetection element 103 are improved. In other words, the response of the photodetection element 103 to the light can be accelerated.

### (High Refractive Index Layer)

The material of the high refractive index layer 31 is the same as that of the high refractive index layer 30 of the first and second embodiments and may include at least one material selected from the group consisting of germanium, silicon, tantalum oxide, silicon nitride, titanium oxide, gallium oxide, hafnium oxide, niobium oxide, zinc sulfide, zirconium oxide, and cerium oxide. The high refractive index layer 31 has, for example, a refractive index larger than that of the metalens 23. The high refractive index layer 31 has, for example, a refractive index larger than that of the insulating layer 40. The high refractive index layer 31 has, for example, a refractive index larger than that of the high thermal conductivity layer 50. The high refractive index layer 31 is, for example, a transparent layer that is transparent to the light in the wavelength range used. For example, the high refractive index layer 31 preferably passes 80% or more of light in the wavelength range used.

The thicknesses of the high refractive index layer 31 and the high thermal conductivity layer 50 can be appropriately set in consideration of the light transparency, the light spot diameter, the heat dissipation performance, and the like.

### (Production Process)

The production process from the second electrode 12 to the first electrode 11 and the insulating layer 42 is the same as that of the first and second embodiments. In the third embodiment, the high thermal conductivity layer 50 and the high refractive index layer 31 are laminated in this order in the positive direction of the z-axis on the first electrode 11 and the insulating layer 42, and the metalens 23 is formed on the high refractive index layer 31 by the above-mentioned method. The high thermal conductivity layer 50 may be formed by, for example, sputtering, and may be laminated multiple times. The high refractive index layer 31 may be formed by, for example, sputtering, and may be laminated multiple times.

As described above, in the photodetection element 103 of the third embodiment, the light passes through the high refractive index layer 31 which has a refractive index larger than that of the metalens 23, so that the spot of light irradiated on the magnetic element 10 can be made smaller. This makes it possible for the thermal energy generated by the light to be efficiently absorbed by the magnetic element 10, thereby improving the sensitivity of the photodetection element 103. In addition, the photodetection element 103 of the third embodiment includes a high thermal conductivity layer 50 which has a thermal conductivity higher than that of the high refractive index layer 31, so that the heat dissipation performance of the photodetection element 103 can be improved.

### Fourth Embodiment

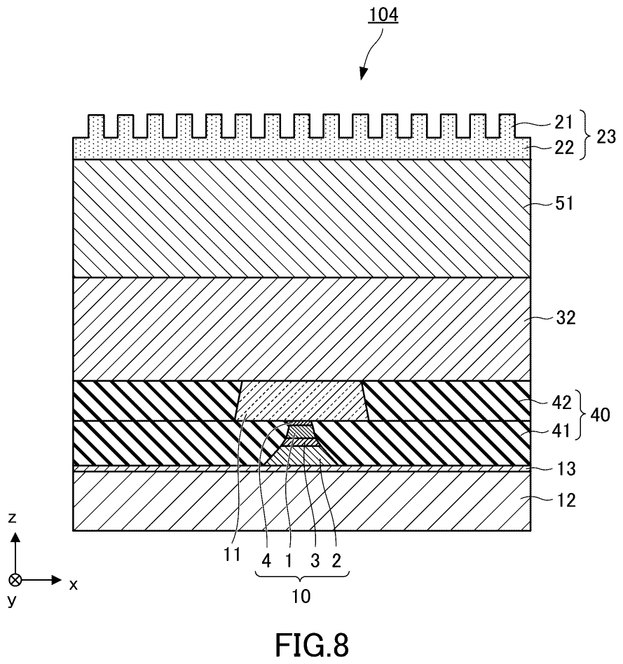

Next, a fourth embodiment of the present invention will be described. FIG. 8 is a cross-sectional view showing the configuration of a photodetection element 104 according to a fourth embodiment of the present invention. In the fourth embodiment, the laminating order in the positive direction of the z-axis of the high refractive index layer 32 and the high thermal conductivity layer 51 provided between the metalens 23 and the magnetic element 10 is different from that of the third embodiment. The other configurations of the fourth embodiment are the same as those of the third embodiment, and therefore the same components of the fourth embodiment are given the same reference numerals, so that the description of the same components will be omitted appropriately.

### (High Thermal Conductivity Layer)

The high thermal conductivity layer 51 is provided between the metalens 23 and the magnetic element 10, and between the metalens 23 and the high refractive index layer 32. Specifically, the high refractive index layer 32 and the high thermal conductivity layer 51 are laminated in this order on the first electrode 11 and the insulating layer 42, and the metalens 23 is provided on the high thermal conductivity layer 51. The high thermal conductivity layer 51 has, for example, a thermal conductivity higher than that of the high refractive index layer 32. The high thermal conductivity layer 51 may have, for example, a thermal conductivity higher than that of either or both the insulating layer 40 and the first electrode 11. The high thermal conductivity layer 51 may have, for example, higher thermal conductivity than the metalens 23. The thermal conductivity of the high thermal conductivity layer 51 is, for example, larger than 40 W/m·K. A portion of the heat generated in the magnetic element 10 and the first electrode 11 is discharged from the high thermal conductivity layer 51 through the high refractive index layer 32.

The material of the high thermal conductivity layer 51 is the same as that of the high thermal conductivity layer 50 of the third embodiment. The high thermal conductivity layer 51 passes light in the band range of use.

Similarly to the third embodiment, the photodetection element 104 of the fourth embodiment can convert light irradiated to the magnetic element 10 into an electrical signal by replacing the light irradiated to the magnetic element 10 with the output voltage from the magnetic element 10. In addition, the high thermal conductivity layer 51 which has a high thermal conductivity, is placed on the outside of the magnetic element 10 which generates heat when irradiated with light, so that the heat conducted from the magnetic element 10 to the high refractive index layer 32 through the first electrode 11 or the insulating layer 40 can be efficiently discharged. In other words, when the irradiation of light to the first ferromagnetic layer 1 is stopped, the magnetic element 10 is quickly cooled, and the magnetization M1 quickly returns to its initial state. If the magnetization M1 of the first ferromagnetic layer 1 quickly returns to its initial state, the light responsive characteristics of the photodetection element 104 are improved. In other words, the response of the photodetection element 104 to the light can be accelerated.

### (High Refractive Index Layer)

The material of the high refractive index layer 32 is the same as that of the high refractive index layer 31 of the third embodiment. The high refractive index layer 32 has, for example, a refractive index larger than that of the metalens 23. The high refractive index layer 32 has, for example, a refractive index larger than that of the insulating layer 40. The high refractive index layer 32 has, for example, a refractive index larger than that of the high thermal conductivity layer 51. The high refractive index layer 32 is, for example, a transparent layer that is transparent to the light in the wavelength range used. It is preferable that the high refractive index layer 32 pass, for example, 80% or more of the light in the wavelength range used.

The thicknesses of the high refractive index layer 32 and the high thermal conductivity layer 51 can be appropriately set in consideration of the light transparency, the light spot diameter, the heat dissipation performance, and the like.

### (Production Process)

The production process from the second electrode 12 to the first electrode 11 and the insulating layer 42 is the same as those of the first to third embodiments. In the fourth embodiment, the high refractive index layer 32 and the high thermal conductivity layer 51 are laminated in this order in the positive direction of the z-axis on the first electrode 11 and the insulating layer 42, and the metalens 23 is formed on the high thermal conductivity layer 51 and the high refractive index layer 32 by the above-mentioned method. The high refractive index layer 32 may be formed by, for example, sputtering, and may be laminated multiple times. The high thermal conductivity layer 51 may be formed by, for example, sputtering, and may be laminated multiple times.

As described above, the photodetection element 104 of the fourth embodiment can reduce the spot of light irradiated on the magnetic element 10 by passing the light through the high refractive index layer 32 which has a refractive index larger than that of the metalens 23. This makes it possible for the magnetic element 10 to efficiently absorb the thermal energy generated by the light, so that the sensitivity of the photodetection element 104 can be improved. In addition, the photodetection element 104 of the fourth embodiment can improve the heat dissipation performance of the photodetection element 104 by being provided with the high thermal conductivity layer 51 which has a thermal conductivity higher than that of the high refractive index layer 32.

### Fifth Embodiment

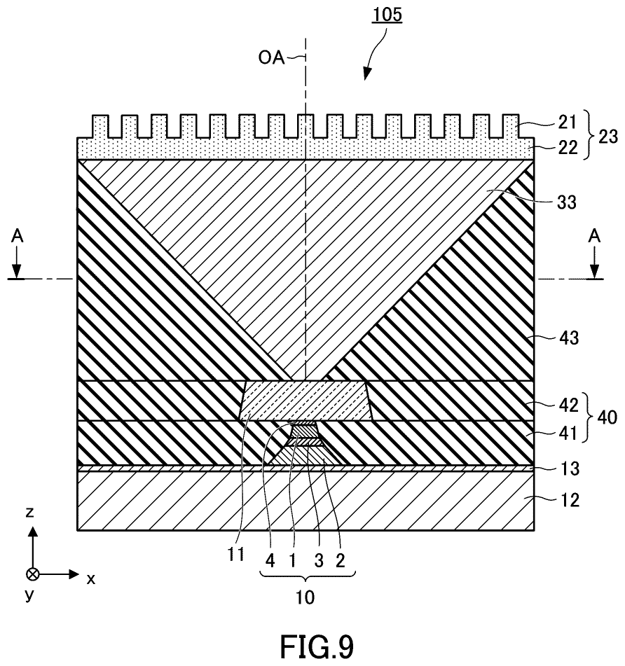

Next, a fifth embodiment of the present invention will be described. FIG. 9 is a cross-sectional view showing the configuration of a photodetection element 105 according to a fifth embodiment of the present invention. The fifth embodiment differs from the second embodiment in the shape of the high refractive index layer 33, and the like. The other configurations of the fifth embodiment are the same as those of the second embodiment, and the same components are given the same reference numerals, so that the description of the same components will be omitted appropriately.

### (Configuration)

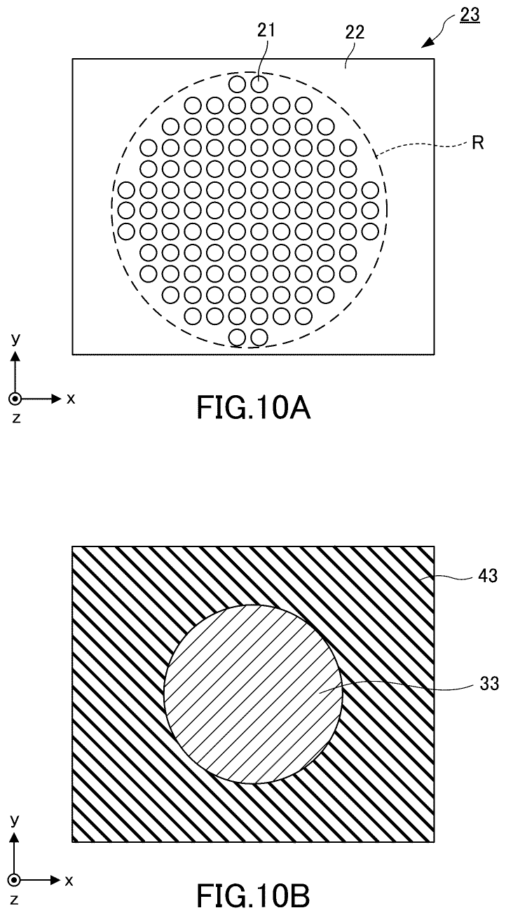

FIG. 10A is a plan view of FIG. 9, and FIG. 10B is a cross-sectional view taken along line A-A of FIG. 9. As can be seen from FIGS. 9 and 10, the high refractive index layer 33 has a structure in which the area of a cross-section perpendicular to the optical axis OA of the metalens 23 gradually decreases from the metalens 23 toward the magnetic element 10. The high refractive index layer 33 is, for example, a truncated cone shape tapered downward (negative z-axis direction), but may also be a truncated pyramid shape, a cone shape, a pyramid shape, or the like. In the case of a truncated cone shape, the high refractive index layer 33 has an upper surface and a lower surface perpendicular to the z-axis direction, and an inclined side surface at the outer surface thereof. The upper surface of the high refractive index layer 33 is provided in contact with the lower surface of the metalens 23 and has a size including the region R in FIG. 10A. The lower surface of the high refractive index layer 33 is provided in contact with the upper surface of the first electrode 11. The high refractive index layer 33 is preferably provided to include at least the optical path OP (see FIG. 6) along which the light travels from the metalens 23 to the first electrode 11. The size of the lower surface of the high refractive index layer 33 may be set to include at least the area where the entire optical path appearing when a light spot is formed in the first electrode 11 or the first ferromagnetic layer 1 intersects with the upper surface of the first electrode 11.

### (High Refractive Index Layer)

The material of the high refractive index layer 33 is the same as that of the high refractive index layer 30 in the first embodiment. The high refractive index layer 33 has, for example, a refractive index larger than that of the metalens 23. The high refractive index layer 33 has, for example, a refractive index larger than that of the insulating layer 40 or the insulating layer 43. The high refractive index layer 33 is, for example, a transparent layer that is transparent to light in the wavelength range used. The high refractive index layer 33 preferably passes, for example, 80% or more of light in the wavelength range used. The film thickness of the high refractive index layer 33, i.e., the thickness in the z-axis direction, is, for example, 100 nm˜1 mm.

### (Insulating Layer)

The high refractive index layer 33 is surrounded by an insulating layer 43 around the periphery of the part where the cross-sectional area perpendicular to the optical axis OA of the metalens 23 gradually decreases, i.e., the side of the truncated cone shaped part. The material of the insulating layer 43 is the same as that of the insulating layer 41 or 42 constituting the insulating layer 40 but may be different from that of the insulating layer 41 or 42.

### (Production Process)

The production process from the second electrode 12 to the first electrode 11 and the insulating layer 42 is the same as that of the first to fourth embodiments. In the fifth embodiment, a high refractive index layer 33 having, for example, a truncated cone shape is formed on the first electrode 11 and the insulating layer 42, and an insulating layer 43 is formed to fill the periphery of the high refractive index layer 33. The metalens 23 is formed on the upper surface of the high refractive index layer 33 by the method described above.

The high refractive index layer 33 and the insulating layer 43 may be formed by, for example, forming a high refractive index layer film on the first electrode 11 and the insulating layer 42 by sputtering, forming a truncated cone shaped high refractive index layer 33 by photolithography and etching, and then embedding the periphery of the high refractive index layer 33 with the insulating layer 43. If necessary, the upper surfaces of the high refractive index layer 33 and the insulating layer 43 may be flattened by, for example, chemical mechanical polishing. The high refractive index layer 33 and the insulating layer 43 may be formed in a laminated shape by repeating the above process while gradually increasing the size of the truncated cone shaped portion.

Alternatively, the high refractive index layer 33 and the insulating layer 43 may be formed by, for example, forming an insulating layer film on the first electrode 11 and the insulating layer 42 by sputtering, forming a truncated cone shaped through hole portion in the center of the upper surface of the insulating layer film by photolithography and etching, and forming the high refractive index layer 33 in the through hole portion formed. If necessary, the upper surfaces of the high refractive index layer 33 and the insulating layer 43 may be flattened by, for example, chemical mechanical polishing. The high refractive index layer 33 and the insulating layer 43 may be formed in a laminated shape by repeating the above process while gradually increasing the size of the through hole portion.

As described above, in the photodetection element 105 of the fifth embodiment, the spot of light irradiated on the magnetic element 10 can be made smaller by passing the light through the high refractive index layer 33, which has a refractive index larger than that of the metalens 23. This allows the thermal energy generated by the light to be efficiently absorbed by the magnetic element 10, thereby improving the sensitivity of the photodetection element 105. In addition, in the photodetection element 105 of the fifth embodiment, the high refractive index layer 33 can be efficiently arranged with respect to the optical path OP from the metalens 23 to the magnetic element 10 or the first electrode 11 of the incident light.

### Sixth Embodiment

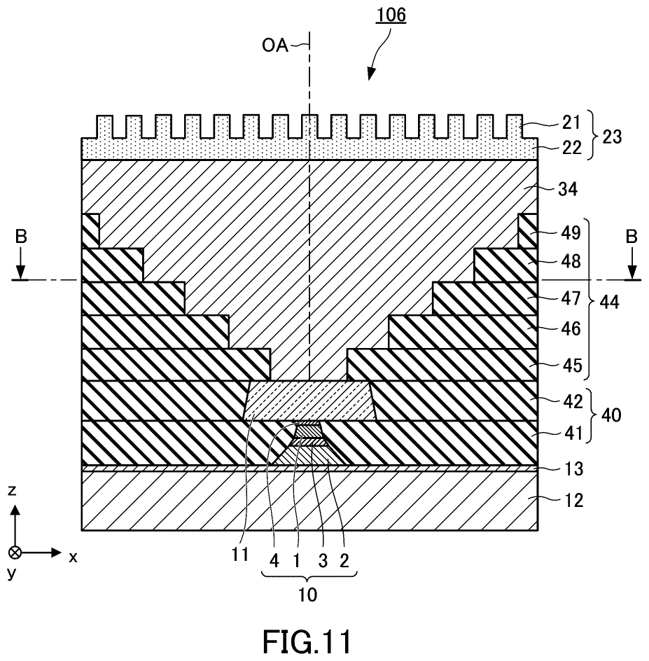

Next, a sixth embodiment of the present invention will be described. FIG. 11 is a cross-sectional view showing the configuration of a photodetection element 106 according to a sixth embodiment of the present invention. The sixth embodiment differs from the fifth embodiment in the shapes of the high refractive index layer 34 and the insulating layer 44. The other configuration is the same as that of the fifth embodiment, and the same components are given the same reference numerals, so that the description of the same components will be omitted appropriately.

### (Configuration)

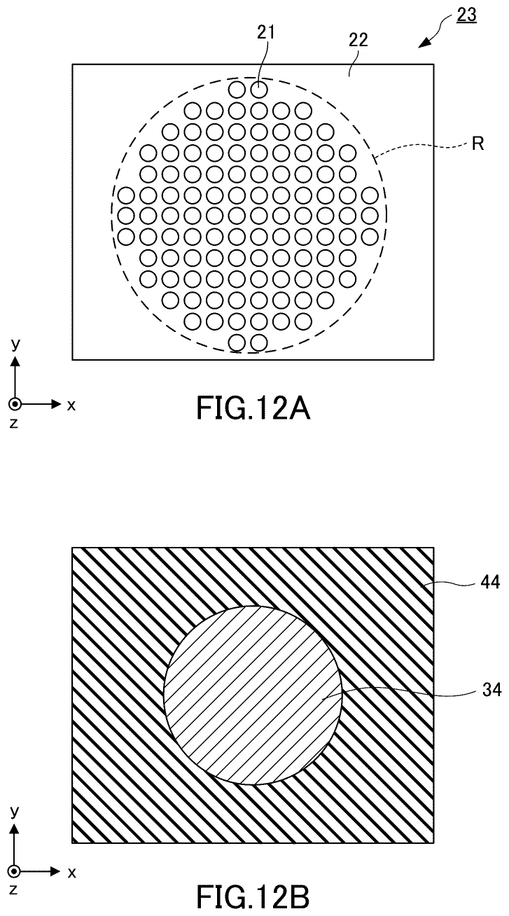

FIG. 12A is a plan view of FIG. 11, and FIG. 12B is a cross-sectional view taken along line B-B of FIG. 11. As can be seen from FIG. 11 FIG. 12A, and FIG. 12B, the high refractive index layer 34 has a structure in which the area of the cross-section perpendicular to the optical axis OA of the metalens 23 decreases in a stepped manner from the metalens 23 toward the magnetic element 10. The high refractive index layer 34 is, for example, formed in such a manner that all or part of the side surface of the high refractive index layer 33 having a truncated cone shape in the fifth embodiment is stepped. The upper surface of the high refractive index layer 34 is provided in contact with the lower surface of the metalens 23 and has a size that includes at least the region R in FIG. 12A. The lower surface of the high refractive index layer 34 is provided in contact with the upper surface of the first electrode 11. The high refractive index layer 34 is preferably provided to include at least the entire optical path OP along which the light travels from the metalens 23 to the first electrode 11. The size of the lower surface of the high refractive index layer 34 may be set, for example, to include at least the area where the optical path OP intersects with the upper surface of the first electrode 11 when a light spot is formed in the first electrode 11 or the first ferromagnetic layer 1.

### (High Refractive Index Layer)

The material of the high refractive index layer 34 is the same as that of the high refractive index layer 33 of the fifth embodiment. The high refractive index layer 34 has, for example, a refractive index larger than that of the metalens 23. The high refractive index layer 34 has, for example, a refractive index larger than that of the insulating layer 40 or the insulating layer 44. The high refractive index layer 34 is, for example, a transparent layer that is transparent to the light in the wavelength range used. The high refractive index layer 34 preferably passes, for example, 80% or more of light in the wavelength range used. The film thickness of the high refractive index layer 34, i.e., the thickness in the z-axis direction, is, for example, 100 nm˜1 mm.

### (Insulating Layer)

The high refractive index layer 34 has a peripheral portion surrounded by an insulating layer 44 and having a cross-sectional area perpendicular to the optical axis OA of the metalens 23 and decreasing stepwise. The insulating layer 44 is a layer having annular insulating layers 45, 46, 47, 48, and 49 each with a circular through hole portion formed in its center and laminated in this order in the positive direction of the z-axis. The number (number of steps) of the above annular insulating layers constituting the insulating layer 44 is not limited to five as shown, but any number can be adopted. The diameter of the circular through hole portion in the center of the annular insulating layers 45, 46, 47, 48, and 49 increases stepwise in this order so that the high refractive index layer 34 at least includes the entire optical path OP of the light from the metalens 23 to the first electrode 11. The layer thicknesses of the annular insulating layers 45, 46, 47, 48, and 49 are the same, but some or all of them may be different from each other. The materials of the insulating layers 45, 46, 47, 48, and 49 are the same as those of the insulating layers 41 and 42 but may be different from each other. The materials of the insulating layers 45, 46, 47, 48, and 49 are all the same, but may be partially or entirely different from each other.

### (Production Process)

The production process from the second electrode 12 to the first electrode 11 and the insulating layer 42 is the same as those of the first to fifth embodiments. In the sixth embodiment, a high refractive index layer 34 with stepped sides and an insulating layer 44 that fills the periphery of the high refractive index layer 34 are formed on the first electrode 11 and the insulating layer 42. A metalens 23 is formed on the upper surface of the high refractive index layer 34 by the method described above.

Specifically, a high refractive index layer film having a predetermined thickness is formed on the first electrode 11 and the insulating layer 42, for example, by sputtering, and the lowest cylindrical portion of the high refractive index layer 34 is formed to have a predetermined thickness by photolithography and etching, and the periphery of the lowest cylindrical portion of the formed high refractive index layer 33 is embedded with the insulating layer 45. If necessary, the upper surfaces of the insulating layer 45 and the lowest cylindrical portion of the high refractive index layer 34 may be flattened by, for example, chemical mechanical polishing. The size of the cylindrical portion of the high refractive index layer 34 is gradually increased while the above process is repeated up to the insulating layer 49, thereby forming the high refractive index layer 34 and the insulating layer 44.

Alternatively, an insulating layer film having a predetermined thickness is formed on the first electrode 11 and the insulating layer 42, for example, by sputtering, and a circular through hole portion is formed in the center of the insulating layer film by photolithography and etching, and the bottom step of the high refractive index layer 34 is formed in the circular through hole portion to be at the same level as the top surface of the insulating layer 45. If necessary, the upper surfaces of the insulating layer 45 and the bottom step of the high refractive index layer 34 may be flattened by, for example, chemical mechanical polishing. The above process is repeated up to the insulating layer 49 while gradually increasing the size of the through hole, thereby forming the high refractive index layer 34 and the insulating layer 44. A high refractive index layer film having a predetermined thickness may be further formed on the upper portion of the insulating layer 49.

As described above, in the photodetection element 106 of the sixth embodiment, the spot of light irradiated on the magnetic element 10 can be made smaller by passing the light through the high refractive index layer 34 which has a refractive index larger than that of the metalens 23. This allows the thermal energy generated by the light to be efficiently absorbed by the magnetic element 10, thereby improving the sensitivity of the photodetection element 106. Furthermore, in the photodetection element 106 of the sixth embodiment, the high refractive index layer 34 can be efficiently arranged using a simple production process with respect to the optical path OP of the incident light travelling from the metalens 23 to the magnetic element 10 or the first electrode 11.

### Seventh Embodiment

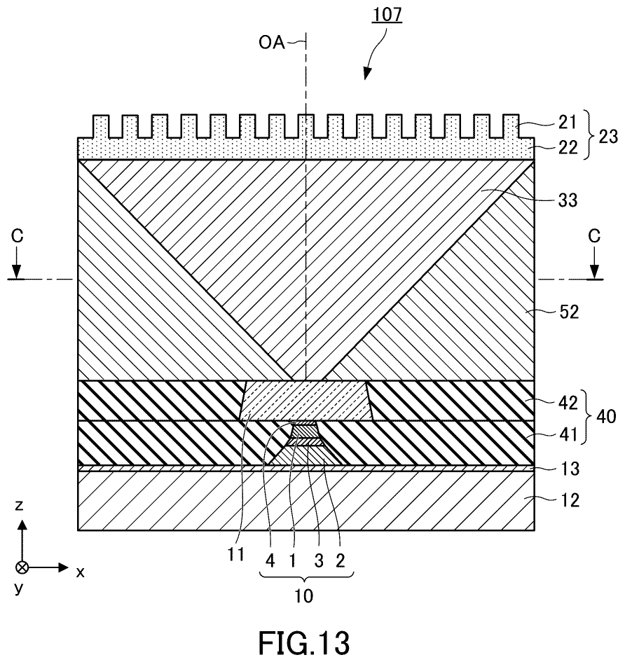

Next, the seventh embodiment of the present invention will be described. FIG. 13 is a cross-sectional view showing the configuration of a photodetection element 107 according to the seventh embodiment of the present invention. The seventh embodiment differs from the fifth embodiment in that the seventh embodiment has a high thermal conductivity refill layer 52. The other configurations of the seventh embodiment are the same as those of the fifth embodiment, and the same components are denoted by the same reference numerals, so that the description of the same components will be omitted appropriately.

### (Configuration)

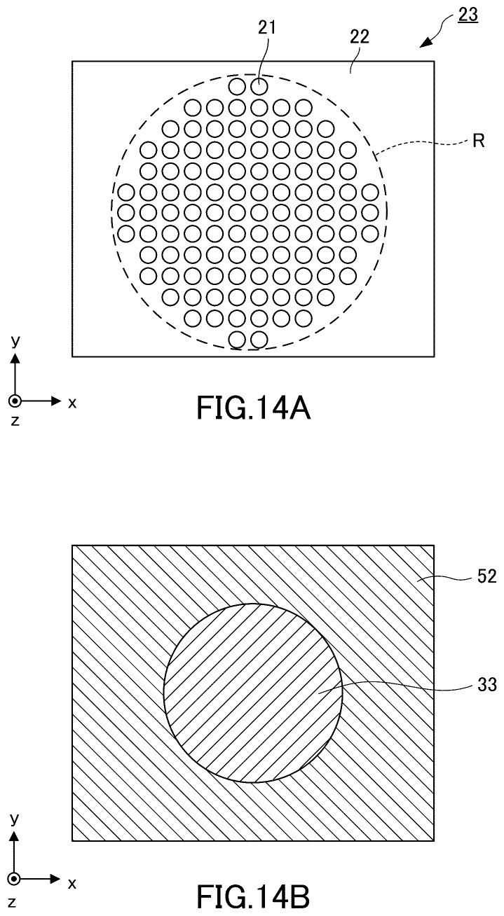

FIG. 14A is a plan view of FIG. 13, and FIG. 14B is a cross-sectional view taken along line C-C of FIG. 13. As can be seen from FIGS. 13 and 14, the high refractive index layer 33 has a structure in which the area of a cross-section perpendicular to the optical axis OA of the metalens 23 gradually decreases from the metalens 23 toward the magnetic element 10. The high refractive index layer 33 is, for example, a truncated cone shape tapered downward (negative z-axis direction), but may also be a truncated pyramid shape, a cone shape, a pyramid shape, or the like. In the case of a truncated cone shape, the high refractive index layer 33 has an upper surface and a lower surface perpendicular to the z-axis direction, and an inclined side surface at the outer surface thereof. The upper surface of the high refractive index layer 33 is provided in contact with the lower surface of the metalens 23 and has a size that at least contains the region R in FIG. 14A. The lower surface of the high refractive index layer 33 is provided in contact with the upper surface of the first electrode 11. The high refractive index layer 33 is preferably provided to include at least the entire optical path OP along which the light travels from the metalens 23 to the first electrode 11. The size of the lower surface of the high refractive index layer 33 may be set to include at least the area where the optical path OP intersects with the upper surface of the first electrode 11 when the light spot is formed by the first electrode 11 or the first ferromagnetic layer 1.

### (High Refractive Index Layer)

The material of the high refractive index layer 33 of the seventh embodiment is the same as that of the high refractive index layer 33 of the fifth embodiment. The high refractive index layer 33 has, for example, a refractive index larger than that of the metalens 23. The high refractive index layer 33 has, for example, a refractive index larger than that of the insulating layer 40. The high refractive index layer 33 has, for example, a refractive index larger than that of the high thermal conductivity refill layer 52. The high refractive index layer 33 is, for example, a transparent layer that is transparent to the light in the wavelength range used. The high refractive index layer 33 preferably passes, for example, 80% or more of light in the wavelength range used. The film thickness of the high refractive index layer 33, i.e., the thickness in the z-axis direction, is, for example, 100 nm˜1 mm.

### (High Thermal Conductivity Refill Layer)

The high refractive index layer 33 is surrounded by a high thermal conductivity refill layer 52 functioning as a high thermal conductivity layer around the periphery of the portion where the cross-sectional area perpendicular to the optical axis OA of the metalens 23 gradually decreases, i.e., around the side of the truncated cone shaped portion. The material of the high thermal conductivity refill layer 52 may be the same as or different from that of the high thermal conductivity layer 50 of the third embodiment or the high thermal conductivity layer 51 of the fourth embodiment. The high thermal conductivity refill layer 52 does not need to be optically transparent. The high thermal conductivity refill layer 52 may have a lower surface in contact with at least a part of the upper surface of the first electrode 11. The high thermal conductivity refill layer 52 may have a lower surface in contact with at least a part of the upper surface of the insulating layer 42.

The photodetection element 107 according to the seventh embodiment can convert light irradiated to the magnetic element 10 into an electrical signal by replacing the light irradiated to the magnetic element 10 with an output voltage from the magnetic element 10. Furthermore, the fact that the high thermal conductivity refill layer 52 having high thermal conductivity is placed on the outside of the magnetic element 10 that generates heat in response to light irradiation can improve heat dissipation from the magnetic element 10 through the first electrode 11 or the insulating layer 40. Also, the heat transferred from the magnetic element 10 to the high refractive index layer 33 through the first electrode 11 can be discharged through the high thermal conductivity refill layer 52. In other words, when the light irradiation to the first ferromagnetic layer 1 is stopped, the magnetic element 10 is quickly cooled, and the magnetization M1 quickly returns to the initial state. If the magnetization M1 of the first ferromagnetic layer 1 quickly returns to the initial state, the response characteristic of the photodetection element 107 to the light is improved. In other words, the response of the photodetection element 107 to the light can be accelerated.

### (Production Process)

The production process of the seventh embodiment from the second electrode 12 to the first electrode 11 and the insulating layer 42 is the same as that of the first to sixth embodiments. In the seventh embodiment, a high refractive index layer 33 having, for example, a truncated cone shape and a high heat conductivity refill layer 52 that fills the periphery of the high refractive index layer 33 are formed on the first electrode 11 and the insulating layer 42. A metalens 23 is formed on the upper surface of the high refractive index layer 33 by the above-mentioned method.

Specifically, the high refractive index layer 33 and the high heat conductivity refill layer 52 may be formed by, for example, forming a high refractive index layer film by sputtering on the first electrode 11 and the insulating layer 42, forming the high refractive index layer 33 having a truncated cone shape by photolithography and etching, and filling the periphery of the high refractive index layer 33 with the high heat conductivity refill layer 52. If necessary, the upper surfaces of the high refractive index layer 33 and the high heat conductivity refill layer 52 may be flattened by, for example, chemical mechanical polishing. The high refractive index layer 33 and the high heat conductivity refill layer 52 may be formed in a laminated shape by repeating the above process while gradually increasing the size of the truncated cone shape portion.

Alternatively, the high refractive index layer 33 and the high thermal conductivity refill layer 52 may be, for example, formed by forming a high thermal conductivity refill layer film on the first electrode 11 and the insulating layer 42 by sputtering, and forming a truncated cone shaped through hole portion at the center of the high thermal conductivity refill film by photolithography and etching, and forming a high refractive index layer 33 in the through hole portion thus formed. If necessary, the upper surfaces of the high refractive index layer 33 and the high thermal conductivity refill layer 52 may be flattened by, for example, chemical mechanical polishing. The high refractive index layer 33 and the high thermal conductivity refill layer 52 may be formed in a laminated shape by repeating the above process while gradually increasing the size of the through hole portion.

As described above, the photodetection element 107 of the seventh embodiment can reduce the spot of light irradiated on the magnetic element 10 by passing the light through the high refractive index layer 33 which has a refractive index larger than that of the metalens 23. This allows the magnetic element 10 to efficiently absorb the heat energy generated by the light, thereby making it possible to improve the sensitivity of the photodetection element 107. In addition, the photodetection element 107 of the seventh embodiment makes it possible for the high refractive index layer 33 to be efficiently arranged on the optical path OP from the metalens 23 to the magnetic element 10 or the first electrode 11. In addition, the photodetection element 107 of the seventh embodiment makes it possible for the high refractive index layer 33 to be surrounded by the high thermal conductivity refill layer 52, thereby improving the heat dissipation performance of the photodetection element 107 including the magnetic element 10.

### Eighth Embodiment

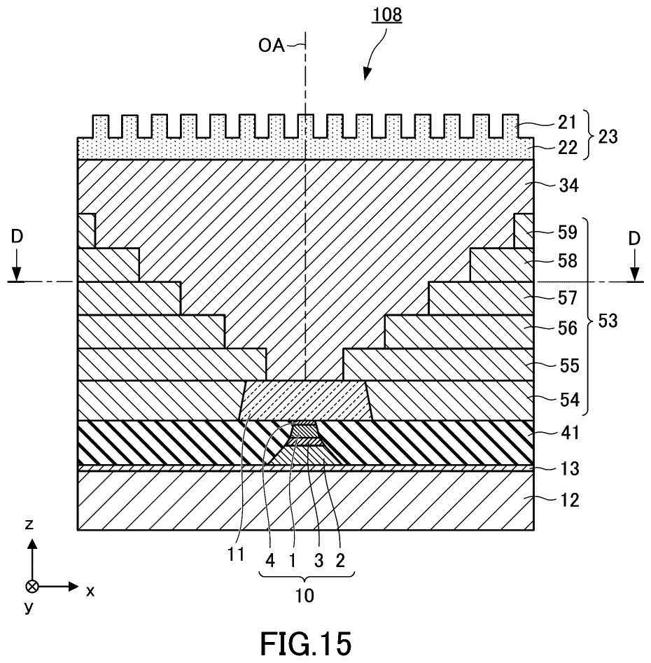

The eighth embodiment of the present invention will be described. FIG. 15 is a cross-sectional view showing the configuration of a photodetection element 108 according to the eighth embodiment of the present invention. The eighth embodiment differs from the sixth embodiment in that the eighth embodiment has a high thermal conductivity refill layer 53. The other configurations are the same as those of the sixth embodiment, and the same components are given the same reference numerals, so that the description of the same components will not be described appropriately.

### (Configuration)

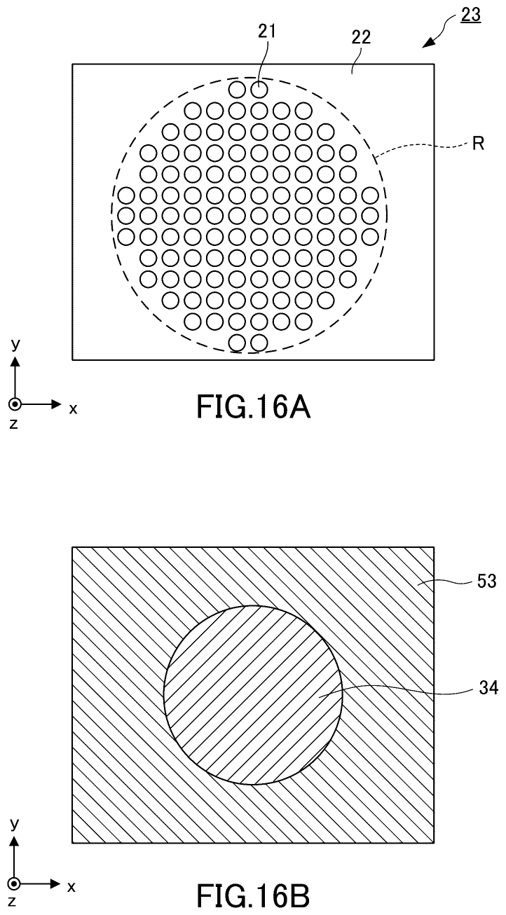

FIG. 16A is a plan view of FIG. 15, and FIG. 16B is a cross-sectional view taken along line D-D of FIG. 15. As can be seen from FIG. 15, FIG. 16A, and FIG. 16B the high refractive index layer 34 has a structure in which the area of a cross-section perpendicular to the optical axis OA of the metalens 23 decreases stepwise from the metalens 23 to the magnetic element 10. The high refractive index layer 34 is formed, for example, by forming all or part of the side surface of the truncated cone shaped high refractive index layer 33 of the seventh embodiment in a stepwise manner. The upper surface of the high refractive index layer 34 is provided in contact with the lower surface of the metalens 23 and has a size that at least includes the region R in FIG. 16A. The lower surface of the high refractive index layer 34 is provided in contact with the upper surface of the first electrode 11. The high refractive index layer 34 is preferably provided to include at least the entire optical path OP along which the light travels from the metalens 23 to the first electrode 11. The size of the lower surface of the high refractive index layer 34 may be set to include at least the area where the optical path OP intersects with the upper surface of the first electrode 11 when the light spot is formed by the first electrode 11 or the first ferromagnetic layer 1.

### (High Refractive Index Layer)

The material of the high refractive index layer 34 of the eighth embodiment is the same as that of the high refractive index layer 34 of the sixth embodiment. The high refractive index layer 34 has, for example, a refractive index larger than that of the metalens 23. The high refractive index layer 34 has a refractive index larger than that of the high thermal conductivity refill layer 53, for example. The high refractive index layer 34 is, for example, a transparent layer that is transparent to light in the wavelength range used. The high refractive index layer 34 preferably passes, for example, 80% or more of light in the wavelength range used. The film thickness of the high refractive index layer 34, i.e., the thickness in the z-axis direction, is, for example, 100 nm˜1 mm.

### (High Thermal Conductivity Refill Layer)

The high refractive index layer 34 is surrounded by a high thermal conductivity refill layer 53 around the periphery of the portion where the area of the cross-section perpendicular to the optical axis OA of the metalens 23 decreases stepwise. The high thermal conductivity refill layer 53 is a layer in which annular high thermal conductivity layers 54, 55, 56, 57, 58, and 59 with a circular through hole portion formed in its center are laminated in this order in the positive direction of the z axis. The number (number of steps) of high thermal conductivity layers constituting the high thermal conductivity refill layer 53 is not limited to six as shown, but any number can be adopted. The annular high thermal conductivity layer 54 is formed to surround the periphery of the first electrode 11. The diameters of the circular through hole portions in the centers of the annular high thermal conductivity layers 55, 56, 57, 58, and 59 increase stepwise in this order to have the high refractive index layer 34 at least include the entire optical path OP of the light from the metalens 23 to the first electrode 11. The thicknesses of the high thermal conductivity layers 54, 55, 56, 57, 58, 59 may be the same or may be partially or entirely different from each other. The material of each of the high thermal conductivity layers 54, 55, 56, 57, 58, 59 is the same as those of the high thermal conductivity layer 50 of the third embodiment, the high thermal conductivity layer 51 of the fourth embodiment, or the high thermal conductive refill layer 52 of the seventh embodiment. The materials of the high thermal conductivity layers 54, 55, 56, 57, 58, 59 may be the same or may be partially or entirely different from each other.

### (Production Process)

The production process from the second electrode 12 to the magnetic element 10 and the insulating layer 41 is the same as those of the first to seventh embodiments. In the eighth embodiment, the first electrode 11 and the high thermal conductivity layer 54 or insulating layer are formed on the magnetic element 10 and the insulating layer 41, and the high refractive index layer 34 and the high thermal conductivity refill layer 53 that fills the periphery of the high refractive index layer 34 are further formed thereon. The metalens 23 is formed on the upper surface of the high refractive index layer 34 by the method described above.

Specifically, a high refractive index layer film having a predetermined thickness is formed on the first electrode 11 and the high thermal conductivity layer 54, for example, by sputtering, and the bottommost cylindrical portion of the high refractive index layer 34 is formed, for example, by photolithography and etching, and the periphery of the cylindrical portion of the formed high refractive index layer 34 is filled with the high thermal conductivity layer 55. If necessary, the upper surfaces of the high thermal conductivity layer 55 and the bottommost cylindrical portion of the high refractive index layer 34 may be flattened, for example, by chemical mechanical polishing. By gradually increasing the size of the cylindrical portion and repeating the above process up to the high thermal conductivity layer 59, the high refractive index layer 34 and the high thermal conductivity refill layer 53 can be formed in a laminated state.

Alternatively, a high thermal conductivity layer film having a predetermined thickness is formed on the first electrode 11 and the high thermal conductivity layer 54, for example, by sputtering, and a circular through hole portion is formed in the center of the high thermal conductivity layer film by photolithography and etching, and the bottommost cylindrical portion of the high refractive index layer 34 is formed in the through hole portion formed. If necessary, the upper surfaces of the high thermal conductivity layer 55 and the bottommost cylindrical portion of the high refractive index layer 34 may be flattened by, for example, chemical mechanical polishing. By gradually increasing the size of the through hole portion and repeating the above process up to the high thermal conductivity layer 59, the high refractive index layer 34 and the high thermal conductivity refill layer 53 can be formed in a laminated state.

As described above, in the photodetection element 108 of the eighth embodiment, the light passes through the high refractive index layer 34 which has a refractive index larger than that of the metalens 23, so that the spot of light irradiated on the magnetic element 10 can be made smaller. This allows the thermal energy generated by the light to be efficiently absorbed by the magnetic element 10, thereby making it possible to improve the sensitivity of the photodetection element 107. In addition, the photodetection element 108 of the eighth embodiment makes it possible for the high refractive index layer 34 to be efficiently arranged, using a simple production process, with respect to the optical path OP from the metalens 23 to the magnetic element 10 or the first electrode 11 of the incident light. In addition, the photodetection element 108 of the eighth embodiment has the high refractive index layer 34 surrounded by the high thermal conductivity refill layer 53, so that the heat dissipation performance of the photodetection element 108 including the magnetic element 10 can be improved.

### Application Example

The photodetection elements 101 to 108 of the first to eighth embodiments can be applied to, for example, an optical sensor such as an image sensor in which a plurality of photodetection elements are arranged one-dimensionally or two dimensionally. Such optical sensors can be used in information terminal devices such as smartphones, tablets, personal computers, and digital cameras.

Furthermore, the photodetection elements 101 to 108 of the first to eighth embodiments can be applied to photoelectric conversion elements of a receiver provided in a transmitter/receiver that transmits and receives optical signals such as laser light in a communication system in which a plurality of transmitter/receivers are connected by optical fibers. The above communication system may be, for example, a communication system that performs short or medium distance communication such as within a data center or between data centers, or long distance communication such as between cities. The transmitter/receiver is installed, for example, in a data center.

Furthermore, the above communication system may be, for example, a communication system that wirelessly transmits and receives optical signals such as near infrared light between mobile terminals such as smartphones and tablets. The above communication system may be, for example, a communication system that wirelessly transmits and receives optical signals such as near infrared light between a mobile terminal and an information processing device such as a personal computer.

The present invention is not limited to the above embodiments, and various modifications and changes can be made within the scope of the gist of the present invention described in the claims.

As described above, the present invention can achieve an excellent effect by concentrating irradiated light in a narrow area to suppress the loss of light energy, thereby making it possible to perform efficient photodetection, and is useful for photodetection elements in general.

### EXPLANATION OF SYMBOLS

1 First ferromagnetic layer
2 Second ferromagnetic layer
3 Spacer layer
4, 13 Cap layer
10 Magnetic element
11 First electrode
12 Second electrode
15 Laminate
20 Lens
21 Nanostructure
22 Base portion
23 Metalens
30, 31, 32, 33, 34 High refractive index layers
40, 41, 42, 43, 44, 45, 46, 47, 48, 49, 140 Insulating layers
50, 51, 54, 55, 56, 57, 58, 59 High thermal conductivity layers
52, 53 High thermal conductivity refill layers
101, 102, 103, 104, 105, 106, 107, 108 Photodetection elements
M1, M2 Magnetization
OA Optical axis
OP Optical path
R Region
S Light spot

What is claimed is:

1. A photodetection element comprising:
a lens;
a magnetic element including a first ferromagnetic layer, a second ferromagnetic layer, and a spacer layer sandwiched between the first ferromagnetic layer and the second ferromagnetic layer; and
a high refractive index layer provided between the lens and the magnetic element and having a refractive index larger than that of the lens;
wherein light that passes through the lens and the high refractive index layer is irradiated onto the magnetic element.

2. The photodetection element according to claim 1, wherein the lens is a metalens which comprises a plurality of nanostructures arranged two dimensionally.

3. The photodetection element according to claim 2, further comprising a high thermal conductivity layer provided between the lens and the magnetic element and having a thermal conductivity higher than that of the high refractive index layer.

4. The photodetection element according to claim 3, wherein the high thermal conductivity layer is provided between the high refractive index layer and the magnetic element.

5. The photodetection element according to claim 3, wherein the high thermal conductivity layer is provided between the lens and the high refractive index layer.

6. The photodetection element according to claim 3, wherein the high refractive index layer has a refractive index higher than that of the high thermal conductivity layer.

7. The photodetection element according to claim 3, wherein the high refractive index layer has a structure with an area of a cross-section perpendicular to the optical axis of the lens gradually decreasing from the lens toward the magnetic element.

8. The photodetection element according to claim 7, wherein the high refractive index layer is surrounded by an insulating layer at a portion where the cross-sectional area perpendicular to the optical axis of the lens gradually decreases.

9. The photodetection element according to claim 8, wherein the high refractive index layer has a refractive index higher than that of the insulating layer surrounding the high-refractive index layer.

10. The photodetection element according to claim 3, wherein the high refractive index layer has a structure with an area of a cross-section perpendicular to the optical axis of the lens decreasing stepwise from the lens toward the magnetic element.

11. The photodetection element according to claim 10, wherein the high refractive index layer is surrounded by an insulating layer at a periphery of a portion with an area of a cross-section perpendicular to the optical axis of the lens decreasing stepwise.

12. The photodetection element according to claim 11, wherein the high refractive index layer has a refractive index higher than that of the insulating layer surrounding the high-refractive index layer.

13. The photodetection element according to claim 7, wherein the high refractive index layer is surrounded by the high thermal conductivity layer at a portion where the cross-sectional area perpendicular to the optical axis of the lens gradually decreases.

14. The photodetection element according to claim 13, wherein the high refractive index layer has a refractive index higher than that of the high thermal conductivity layer surrounding the high-refractive index layer.

15. The photodetection element according to claim 10, wherein the high refractive index layer is surrounded by the high thermal conductivity layer at a periphery of a portion with an area of a cross-section perpendicular to the optical axis of the lens decreasing gradually or stepwise.

16. The photodetection element according to claim 15, wherein the high refractive index layer has a refractive index higher than that of the high thermal conductivity layer surrounding the high-refractive index layer.

17. The photodetection element according to claim 1, wherein the high refractive index layer is made of at least one material selected from the group consisting of germanium, silicon, tantalum oxide, silicon nitride, titanium oxide, gallium oxide, hafnium oxide, niobium oxide, zinc sulfide, zirconium oxide, and cerium oxide.

18. A photodetection element comprising:
a lens,
a magnetic element including a first ferromagnetic layer, a second ferromagnetic layer, and a spacer layer sandwiched between the first ferromagnetic layer and the second ferromagnetic layer,
an insulating layer provided to cover the periphery of the magnetic element, and
a high refractive index layer having a refractive index larger than that of the insulating layer,
wherein light that passes through the lens and the high refractive index layer is irradiated onto the magnetic element.

19. An information terminal device using a photodetection element according to claim 1.

20. A communication system using a photodetection element according to claim 1.

21. A method for manufacturing a photodetection element that detects light passing through a lens, comprising:
forming a magnetic element as a magnetoresistance effect element, the magnetic element having a first ferromagnetic layer, a second ferromagnetic layer, and a spacer layer sandwiched between the first ferromagnetic layer and the second ferromagnetic layer;
forming a high-refractive index layer between the lens and the magnetic element, the high-refractive index layer having a refractive index higher than that of the lens.

22. The method for manufacturing a photodetection element according to claim 21, further comprising forming an insulating layer having a refractive index lower than that of the high refractive index layer so as to cover a side surface of the magnetic element.
